(19) United States
(12) Patent Application Publication
(10) Pub. No.: US 2026/0047224 A1
(43) Pub. Date: Feb. 12, 2026

(54) CHARGE DAMAGE PROTECTION FOR TRENCH ISOLATION

(71) Applicant: SEMICONDUCTOR COMPONENTS INDUSTRIES, LLC, Scottsdale, AZ (US)

(72) Inventors: Manuel H. INNOCENT, Wezemaal (BE); Jeffrey Peter GAMBINO, Gresham, OR (US); James Joseph STEFFES, Poughkeepsie, NY (US); Ryan RETTMANN, Hopewell Junction, NY (US); Byeong Yeol KIM, Lagrangeville, NY (US)

(73) Assignee: SEMICONDUCTOR COMPONENTS INDUSTRIES, LLC, Scottsdale, AZ (US)

(21) Appl. No.: 18/795,919

(22) Filed: Aug. 6, 2024

(51) Int. Cl. H01L 27/146

(52) U.S. Cl. CPC H10F 39/807; H10F 39/014; H10F 39/811; H10F 39/18

(57) ABSTRACT

Systems, devices, and methods are described to protect isolation trench structures from charge damage during plasma-based BEOL deposition and etching steps. Devices and methods may include image sensors having array isolation trenches in an array portion of the image sensor substrate including a pixel array. A periphery portion of the substrate may include isolation trenches coupled with a metallization layer at a frontside of the substrate. The periphery portion may also include contacts between substrate segments and the metallization layer. The substrate and periphery trenches remain at the same potential during BEOL processing, reducing the risk of charge damage to the isolation trenches. In some embodiments, the periphery trenches may remain isolated from the array trenches until BEOL processing is complete, for example being coupled by conductive material after backside thinning. The array trenches may be coupled, through the periphery portion, for biasing in the completed image sensor.

### BACKGROUND

This application relates generally to image sensors, and, more particularly, to image sensors having trench isolation structures interposed between adjacent pixels.

Image sensors are used in many electronic devices, such as cameras, smart phones, computers, and so on, to capture images and/or video, among other possible functions. Image sensors typically include an array of image pixels arranged in rows and columns. Each pixel may contain a photodiode for generating charge in response to incident photons. The pixel array may contain isolation structures between each pixel to prevent electrical crosstalk, prevent light leakage, improve internal reflection, and so on.

The pixel array may be covered by a color filter array. Various circuitry may be coupled to each pixel, pixel column, and/or pixel row for storing generated charge, transferring such charge, converting the charge to a digital representation, and/or for other readout and processing purposes. Therefore, one or more conductive signal lines (also referred to herein as metal routing layers or metal layers) may be connected with each pixel and/or various structures of the pixel array. The conductive signal lines may extend within the array and external to the array (referred to herein as the periphery of the sensor, or just the periphery). In some cases, the isolation structures may be biased to reduce dark current.

Backside image sensor (BSI) may first have processing steps performed from a frontside (FS) of the substrate of the image sensor. Such processing steps may include forming the various pixel structures in the substrate such as the photodiode, transfer transistor and other functional components, as well as isolation structures. Frontside processing may also include forming various structures, circuitry, and the like in the periphery, and one or more metal routing layers for the image sensor.

Various plasma processes may be used to perform the etching, deposition, and the like required to form the image sensor, in particular during formation of the metal routing layers. However, plasma processes may charge various metal layers and interconnects. For image sensors having biased isolation structures, the isolation structures may be contacted from the frontside but excess charge from plasma processes may build up within the isolation structures. The excess charge may create electric fields that can affect the surrounding materials. Dielectric materials such as silicon dioxide or low-k dielectrics may be susceptible to damage from these electric fields. For example, high electric fields can cause dielectric breakdown and may lead to the formation of undesirable defects such as pinholes, voids, or the like. Backside isolation structures may be formed after frontside processing to avoid charge damage, but the backside trench and backside contact to the trench may be expensive to form.

It would therefore be desirable to provide improved devices and methods for image sensors having biased isolation structures.

### BRIEF DESCRIPTION OF DRAWING FIGURES

FIG. 1 is a schematic diagram showing an exemplary device that includes an image sensor, according to various embodiments.

FIG. 2A is a plan view of a first exemplary arrangement of isolation trenches for an image sensor, according to various embodiments.

FIG. 2B is a cross-sectional side view taken along and in the direction of line 1-1 in FIG. 2A, illustrating isolation trenches after BEOL processing according to various embodiments.

FIG. 2C is a cross-sectional side view taken along and in the direction of line 1-1 in FIG. 2A, illustrating isolation trenches after backside thinning according to various embodiments.

FIG. 3A is a plan view of a second exemplary arrangement of isolation trenches for an image sensor, according to various embodiments.

FIG. 3B is a cross-sectional side view taken along and in the direction of line 2-2 in FIG. 3A, illustrating isolation trenches after BEOL processing according to various embodiments.

FIG. 3C is a cross-sectional side view taken along and in the direction of line 2-2 in FIG. 3A, illustrating isolation trenches after backside thinning according to various embodiments.

FIG. 4A is a cross-sectional side view illustrating a third exemplary arrangement of isolation trenches after BEOL processing, according to various embodiments.

FIG. 4B is a cross-sectional side view illustrating a third exemplary arrangement of isolation trenches after backside thinning, according to various embodiments.

FIG. 5A is a plan view of a fourth exemplary arrangement of isolation trenches for an image sensor, according to various embodiments.

FIG. 5B is a cross-sectional side view taken along and in the direction of line 3-3 in FIG. 5A, illustrating isolation trenches after backside thinning according to various embodiments.

FIG. 6A is a plan view of a fifth exemplary arrangement of isolation trenches for an image sensor, according to various embodiments.

FIG. 6B is a cross-sectional side view taken along and in the direction of line 4-4 in FIG. 6A, illustrating isolation trenches after backside thinning according to various embodiments.

FIG. 6C is a cross-sectional side view taken along and in the direction of line 4-4 in FIG. 6A, illustrating isolation trenches coupled for biasing on a backside of the image sensor according to various embodiments.

FIG. 7A is a plan view of a sixth exemplary arrangement of isolation trenches for an image sensor, according to various embodiments.

FIG. 7B is a cross-sectional side view taken along and in the direction of line 5-5 in FIG. 7A, illustrating isolation trenches coupled for biasing on a backside of the image sensor according to various embodiments.

FIG. 8A is a plan view of a seventh exemplary arrangement of isolation trenches for an image sensor, according to various embodiments.

FIG. 8B is a cross-sectional side view taken along and in the direction of line 6-6 in FIG. 8A, illustrating isolation trenches coupled for biasing on a backside of the image sensor according to various embodiments.

FIG. 9A is a plan view of an eighth exemplary arrangement of isolation trenches for an image sensor, according to various embodiments.

FIG. 9B is a cross-sectional side view taken along and in the direction of line 7-7 in FIG. 9A, illustrating isolation trenches coupled for biasing on a backside of the image sensor according to various embodiments.

FIG. 10A is a plan view of a first arrangement of an array portion and multiple periphery portions, according to various embodiments.

FIG. 10B is a plan view of a second arrangement of the array portion and multiple periphery portions, according to various embodiments.

FIG. 11 is a simplified flow chart illustrating a method of protecting array trenches during fabrication, according to various embodiments.

### BRIEF SUMMARY

Various embodiments relate to systems, devices, and methods for protecting biased array trenches from charge damage during fabrication of an image sensor or other similar devices.

In various embodiments, a semiconductor device may include a substrate comprising an array portion and a periphery portion, a plurality of substrate segments defined by a plurality of array trenches in the substrate, a first array trench of the plurality of array trenches, wherein the first array trench traverses the array portion and the periphery portion, a second array trench of the plurality of array trenches in the array portion, wherein the first array trench intersects with the second array trench in the array portion, a first trench contact coupled with the first array trench in the periphery portion, and a first substrate contact coupled with a first substrate segment of the plurality of substrate segments in the periphery portion, wherein the first trench contact and the first substrate contact are electrically coupled through a conductive signal line.

In various embodiments, a semiconductor device may include a substrate comprising an array portion and a periphery portion; a plurality of array trenches, comprising a first array trench traversing both the array portion and the periphery portion and a second array trench in the array portion, wherein the first array trench intersects and electrically couples with the second array trench, a periphery trench in the periphery portion, wherein the periphery trench does not intersect any of the plurality of array trenches, a trench contact coupled with the periphery trench in the periphery portion, wherein the trench contact is at a frontside of the substrate, and a conductive layer on a backside of the substrate, wherein the conductive layer couples the periphery trench with the first array trench at the periphery portion.

In various embodiments, a method of forming an image sensor on a substrate may include forming, during front end of line (FEOL) processing, a plurality of deep trenches from a frontside of the substrate, wherein the plurality of deep trenches are formed in an array portion of the substrate and in a periphery portion of the substrate and a first trench of the plurality of deep trenches comprises an array trench traversing the array portion and the periphery portion, forming in the periphery portion, during back end of line (BEOL) processing, a substrate contact to the substrate adjacent to the first trench at the frontside of the substrate, forming an electrical contact to the first trench in the periphery portion, and thinning, after BEOL processing, the substrate from a backside of the substrate.

These and other examples are described in increasing detail below.

### DETAILED DESCRIPTION

The following detailed description is intended to provide several examples that will illustrate the broader concepts that are set forth herein, but it is not intended to limit the invention or the application and uses of the invention. Furthermore, there is no intention to be bound by any theory presented in the preceding background or the following detailed description.

Embodiments according to the present description reduce charge damage from BEOL processes to deep trench structures, for example as used in image sensor pixel arrays. According to various embodiments, array isolation trench structures forming the pixel array of an image sensor may be coupled to metal routing for biasing after BEOL processing. The array trenches may be coupled to trench or other biased structures in a periphery portion of the image sensor through backside connections. According to various embodiments, the array trenches may extend to the periphery portion, where the trenches and the substrate in the periphery portion are electrically shorted through metal routing or other conductive material to the same potential during BEOL processing.

Various embodiments provide array trenches capable of being biased through electrical coupling in the periphery portion of the image sensor. The substrate in the array portion may be isolated from the trenches and substrate in the periphery portion after BEOL processing, and may be biased separately (e.g., grounded) from the substrate in the periphery portion during operation of the image sensor. In some embodiments, the substrate in the periphery portion may be biased to the same voltage as the trenches in the periphery (e.g., −4 V). Some embodiments may provide stacked via contacts to the trenches, having minimized area to minimize a metal antenna ratio. Some embodiments may provide a protection diode in the substrate adjacent to a trench in the periphery portion.

Advantageously, systems, devices, and methods according to the present description provide improved trench isolation structures capable of being biased during operation of the image sensor 14. The improved trench isolation structures may have improved performance due to fewer defects and damage caused by BEOL processing, and may be implemented with relatively inexpensive process steps.

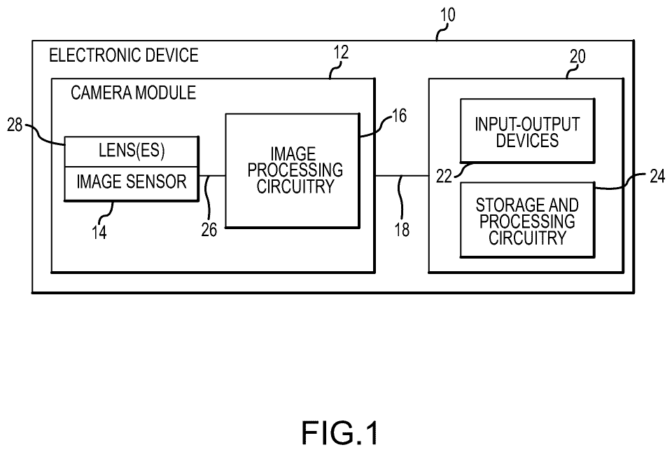

FIG. 1 illustrates an electronic device 10, for example as described above, having a camera module. The camera module 12 (sometimes referred to as an imaging device or imaging system) may include one or more image sensors 14 and one or more lenses 28. During operation, the lenses 28 focus light onto the image sensor 14. The image sensor 14 includes photosensitive elements, such as photodiodes, that convert incident photons into an electrical charge. Image sensors may have any number of pixels (e.g., hundreds, thousands, millions, or more), each including a photosensitive element. The image sensor 14 may include bias circuitry, sample and hold circuitry, correlated double sampling (CDS) circuitry, amplifier circuitry, analog-to-digital (ADC) converter circuitry, data output circuitry, memory circuitry, address circuitry, and the like.

Still and video image data from the image sensor 14 may be provided to image processing circuitry 16, such as via communication path 26. Image processing circuitry 16 may be used to perform image processing functions such as automatic focusing functions, depth sensing, data formatting, adjusting white balance and exposure, implementing video image stabilization, face detection, or the like. Image processing circuitry 16 may also be used to compress raw camera image files if desired, for example to Joint Photographic Experts Group or JPEG format.

In some arrangements, sometimes referred to as a system on chip (SOC) arrangement, the image sensor 14 and image processing circuitry 16 are implemented on a common integrated circuit. In some arrangements, image sensor 14 and image processing circuitry 16 may be implemented using separate integrated circuits. For example, image sensor 14 and image processing circuitry 16 may be formed on separate substrates that have been stacked.

In some arrangements, the image sensor 14 may include bonded substrates. For example, in a backside illuminated (BSI) image sensor, the pixel array, periphery structures and circuitry, and metal routing layers may be formed from a frontside of a first substrate prior to the first substrate being flipped for additional processing such as backside thinning, passivation, color filter array, and microlens formation. The metal routing layers may be used to connect the various components of the pixel, such as the photodiode and readout circuitry, to control and data processing circuitry, or other relevant circuits or structures, elsewhere on the image sensor 14. The frontside of the first substrate may be bonded to a second substrate, for example containing additional pixel control and/or storage structures, readout circuitry, and/or other control and processing circuitry.

The camera module 12 may convey acquired image data to host subsystems 20 over a communication path 18. For example, image processing circuitry 16 may convey image data to subsystems 20. The electronic device 10 may provide a user with numerous high-level functions. In a computer or smart phone, for example, a user may be provided with the ability to run user applications. To implement these functions, host subsystem 20 of electronic device 10 may include storage and processing circuitry 24 and input-output devices 22 such as keypads, input-output ports, joysticks, and displays. The storage and processing circuitry 24 may include volatile and/or nonvolatile memory. The storage and processing circuitry 24 may also include microprocessors, microcontrollers, digital signal processors, application specific integrated circuits, or other processing circuits.

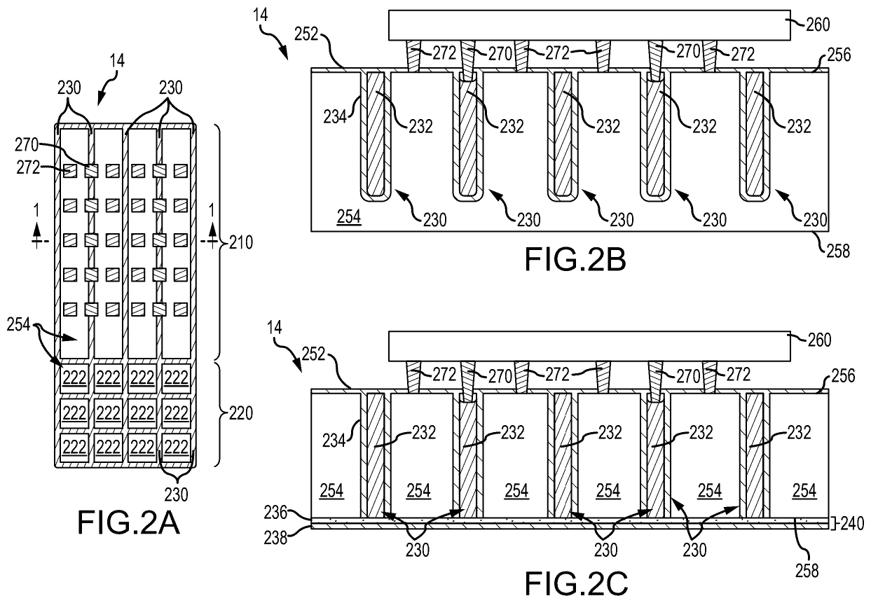

FIG. 2A illustrates a top view of an exemplary image sensor 14 having biased isolation structures, according to various embodiments. The image sensor includes a semiconductor substrate 254, for example silicon. The image sensor 14 may have an array portion 220 and a periphery portion 210. The array portion 220 may include the array of pixels 222 arranged in rows and columns. The periphery portion 210 may be located external to the array portion 220, for example adjacent to the array portion 220, and may include other supporting circuitry and structures. The periphery portion 210 need not include the entire portion of the substrate 254 external to the array portion 220. The isolation structures for the pixel portion 220 may be biased from the periphery portion 210.

In some embodiments, the periphery portion 210 includes structures configured to protect the array portion 220 from charge damage during processing and to provide proper biasing during operation of the image sensor 14. In some embodiments, the periphery portion 210 may further include other structures that support the functionality and operation of the image sensor 14. For example, these structures may include input/output (IO) circuitry, analog and/or digital signal processing circuitry, control logic, clock generation and distribution, power distribution, and/or the like. The periphery may also include structures related to the boundary of the pixel array, such as row and column address decoders for accessing individual pixels.

For the sake of clarity, a simplified subset of the array portion 220 and periphery portion 210 are shown in FIGS. 2A-C. The actual number of trench structures, pixels, substrate and trench connections, and the like may be much higher in many embodiments. Further, because the various trench structures may be electrically coupled throughout the array portion 220 and/or periphery portion 210, some embodiments may include only a subset of the various trench structures and/or substrate portions having trench and/or substrate connections, respectively.

The image sensor 14 may include arrangements of array trench isolation structures 230. The array trenches 230 are those trenches that extend, laterally along the substrate 254, through the array portion 220 and are disposed between adjacent pixels of the pixel array to function as isolation structures. In some embodiments, the array trenches 230 may also extend into the periphery portion 210. The array trenches 230 may include full trench (FT) trenches, deep trench (DT) trenches, and/or any other suitable trench isolation structures. In some embodiments, the array trenches 230 may include deep trench isolation (DTI) structures such as frontside deep trench isolation (FDTI) and/or backside deep trench isolation (BDTI).

Referring to FIG. 2B, in some embodiments array trenches 230 may be formed by etching a trench in the front surface 256 (also referred to as the frontside or FS) of the substrate 254 of the image sensor 14. The array trenches 230 may be etched partially through the substrate 254 in both the array portion 220 and periphery portion 210, such that the array trenches 230 do not intersect a back surface 258 of the substrate and the substrate remains electrically intact throughout the array portion 220 and periphery portion 210, for example as shown in FIG. 2B. The trenches may be lined with an insulating material 234 such as silicon dioxide, silicon nitride, other hi-k or low-k dielectric, and/or the like. The insulating material 234 may be selected based on electrical properties, optical properties, or other desired characteristics and/or functions.

The array trenches 230 may then be filled with a conductive material filler 232 such polysilicon, metal, and/or other material suitable for biasing. In some embodiments, the conductive material filler 232 may include tungsten and/or doped polysilicon. The array trenches 230 of the array portion 220 and periphery portion 210 may be electrically coupled, for example through the conductive filler 232, such that they remain at the same electrical potential. For example, the array trenches 230 may be positively biased, negatively biased, or grounded, as desired during operation of the image sensor 14.

Formation of the array trenches 230 may be performed during front end of line (FEOL) processing of the image sensor 14, for example along with the formation of other semiconductor structures of the pixels, control logic, and so on. Therefore, in some embodiments, the substrate remains electrically intact or otherwise configured to remain at a consistent electrical potential throughout the periphery portion 210 and the array portion 220 at the end of FEOL processing.

One or more trench contacts 270 may be formed to one or more array trenches 230 in the periphery portion 210. One or more substrate contacts 272 may be formed to one or more segments of the substrate 254 in the periphery portion 210. The substrate 254 segments may be those portions of the substrate located between successive trenches. The trench contacts 270 and substrate contacts 272 may be formed during or after FEOL processing as desired. In some embodiments, the trench contacts 270 and/or substrate contacts 272 include conductive vias.

One or more metal routing layers may be formed at the frontside 256 of the substrate 254 during back end of line (BEOL) processing. The metal routing layers may alternate with layers of insulating material such as various oxides. Vias may extend through one or more insulating layers to connect multiple metal layers. For clarity, the various insulating layers are not illustrated. A FS passivation layer 252 (for example, an oxide) at the frontside 256 may be part of a first insulating layer (not shown) between the substrate 254 and a first metal layer 260. The trench contacts 270 and substrate contacts 272 may pass through the passivation layer 252 to electrically couple with the trenches and substrate 254 segments, respectively.

The first metal layer 260 may be formed during BEOL processing. In some embodiments, the first metal layer 260 may be electrically coupled with the trench contacts 270 and substrate contacts 272. Through the first metal layer 260, the substrate 254 segments and array trenches 230 in the periphery portion 210 will be at substantially the same electrical potential. The array trenches 230 in the periphery portion 210 and the array portion 220 will be at substantially the same electrical potential due to the continuous metal filler 232 extending in both the periphery portion 210 and the array portion 220. The substrate 254 segments in the periphery portion 210 and the array portion 220 will be at substantially the same electrical potential due to the electrically intact portions of the substrate extending along the back surface 258 (also referred to herein as the backside or BS) in both the periphery portion 210 and the array portion 220.

Therefore, in some exemplary embodiments, the substrate 254 and array trenches in both the periphery portion 210 and array portion 220 may remain at substantially the same electrical potential during BEOL processing. If various plasma processes performed during BEOL create excess charge on one or more metal layers, the array trenches 230 and the substrate 254 segments will remain at equivalent electrical potential, minimizing or otherwise reducing the electrical field between the array trenches 230 and the surrounding substrate 254. This significantly reduces the risk of charge damage during plasma or other processes inducing charge in the image sensor 14 structures.

After BEOL processing from the FS 256 is complete, there may be little additional risk of charge damage from further processing steps. Referring to FIG. 2C, after BEOL processing from the FS 256, the substrate may be flipped, for example attached to a carrier wafer, and further processed from the BS 258. In some embodiments, the substrate 254 segments of the pixel portion 220 may be electrically separated from the substrate 254 of the periphery portion after BEOL processing, thus allowing the array trenches 230 to be biased independently of the substrate 254 segments of the array portion 220 during operation of the image sensor 14.

In some embodiments, the substrate 254 may be thinned from the BS 258, for example using grinding and/or etching. The substrate 254 may be thinned to at least the array trenches 230, such that one or more substrate 254 segments are no longer in electrical communication. For example, after thinning, the substrate 254 segments in the array portion 220 may be electrically isolated from the substrate 254 segments in the periphery portion 210. The substrate 254 segments in the periphery portion 210 may be electrically isolated from the substrate 254 in other portions of the image sensor 14 external to the array portion 220. In some embodiments, thinning the substrate 254 causes the substrate 254 segments for each pixel in the array portion 220 to become physically and/or electrically isolated from each other, based on desired performance and functionality of each pixel. The substrate 254 segments in the periphery portion 210 may remain electrically coupled with the array trenches 230 through the trench contacts 270 and substrate contacts 272 at the FS 256.

In some embodiments, after thinning, a passivation region 240 may be formed on the BS 258. The passivation region 240 may include anti-reflective coatings (ARC), chemical passivation layer(s), electrically insulating layer(s) such as hi-k or low-k dielectrics, and/or the like. For example, the passivation region 240 may include an insulating layer 238, for example silicon dioxide or silicon nitride, and a hi-k dielectric layer 236. Additional processing from the BS 258 may include forming a color filter array, microlenses, and/or other desired structures (not shown).

Advantageously, according to various embodiments, charge damage to the array trenches 230 during BEOL processing can be prevented, and bias provided to the array trenches 230 during operation of the image sensor 14, using only FS 256 contacts to the substrate 254 and/or array trenches 230. In other words, devices and methods according to various exemplary embodiments may be implemented without including respective BS 258 contacts.

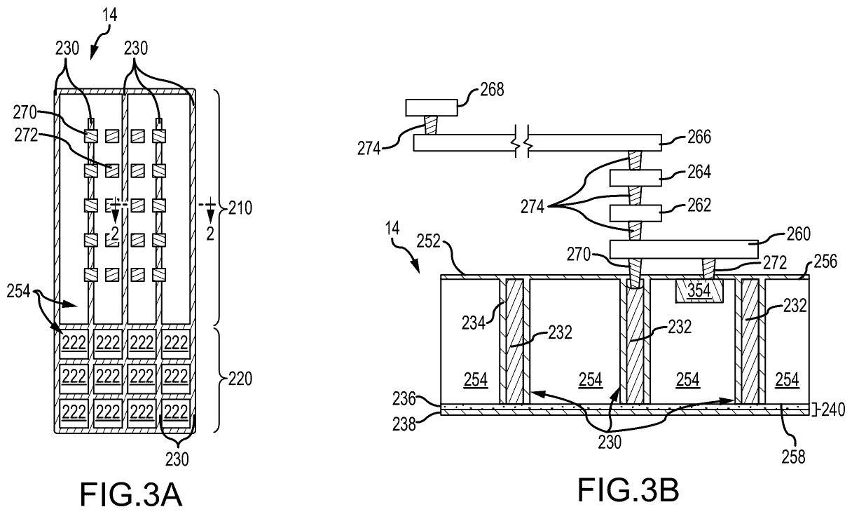

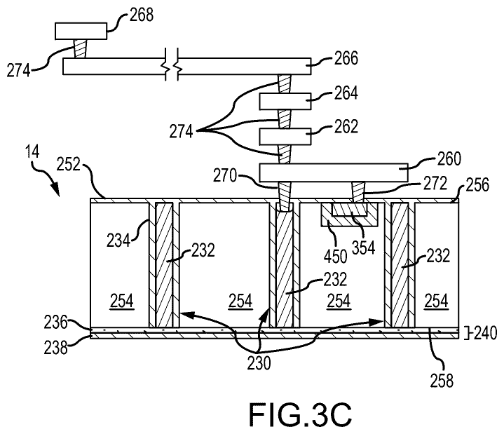

Referring to FIG. 3A, in some exemplary embodiments, the array trenches 230 may form a broken or otherwise incomplete grid in the periphery portion 210, and/or may not each be coupled to the first metal layer 260 through a trench contact 270. The array trenches 230 may nonetheless be fully electrically coupled through intersection with other array trenches 230 in the periphery portion 210 and/or array portion 220. The number and placement of substrate contacts 272 and trench contacts 270 may be chosen based on desired protection during or after BEOL processing, desired performance based on various process parameters and/or requirements, desired functionality during operation of the image sensor 14, and/or any other suitable criteria.

Referring to FIG. 3B, which illustrates the image sensor 14 after backside thinning, in some embodiments the substrate 254 in the periphery portion 210 may include a heavily-doped regions 354 formed and located proximate to the FS 256 and aligned with the substrate contacts 272 to provide improved electrical coupling with the substrate contacts 272. For example, a lightly-doped p-type substrate 254 in the periphery portion 210 may include heavily-dope p-type regions 354 placed for the substrate contacts 272 to land on. The heavily-doped regions 354 may provide an improved discharge path through the substrate 254 during various plasma processes or other processes that generate charge.

In some embodiments, the array contacts 270 and/or substrate contacts 272 may be coupled through one or more reduced-area metal routing layers, to a higher-level metal routing layer spanning a larger portion of the periphery portion 210. The relatively small metal area may function to further protect the substrate 254 and array trenches 230 from charge damage, as the charge may accumulate on metal structures having a larger area.

For example, the number of substrate contacts 272 and array contacts 270 may be reduced as described above, allowing for use of short segments of the first metal layer 260 to couple adjacent contacts 270, 272. The first metal layer 260 may be coupled, though conductive vias 274 and a second metal layer 262 and third metal layer 264 (each having a small area), to a larger area fourth metal layer 266. The fourth metal layer 266 may span a larger portion of the periphery portion 210 and may couple with multiple shorter segments of the first metal layer 260, and may receive more of the charge generated during various plasma processes. The fourth metal layer 266 may further be coupled, through a conductive via 274, to additional metal layers such as a fifth metal layer 268 as desired.

Referring to FIG. 3C, which illustrates the image sensor 14 after backside thinning, in some embodiments a protection diode may be formed in the substrate 254 to protect the array trenches 230 during BEOL processing. In some embodiments, a highly-doped region 354 may be formed in a well 450 of opposite doping to the substrate 254. For example, a highly-doped p-type region 354 may be formed in an n-type well 450, with the highly-doped p-type region 354 forming the anode of the protection diode. The substrate contact 272 may couple with the anode of the protection diode. In other embodiments, the diode may be formed using an oppositely-doped region to the doping of the substrate 254. For example, the diode may be formed from a highly-doped n-type region in a p-type substrate.

During processing that may create charge on the metal layers 260, 262, 264, 266, 268, the protection diode may become forward-biased due to charging and may allow a path for charge to flow into the substrate. Forward biasing of the protection diode may occur at the same time that charge is flowing into the array trenches 230, and therefore the electrical potential of the array trenches 230 and substrate 254 segments remains substantially equal.

The substrate 254 segments in the periphery portion 210 may be substantially electrically isolated from the array trenches 230 through the protection diode during normal operation of the image sensor 14. In some embodiments, biasing the array trenches 230 to a negative value, for example about −4 V, will also reverse bias the protection diode and substantially prevent the substrate 254 from obtaining the same electrical potential as the array trenches 230.

Advantageously, embodiments having a protection diode for the connection between substrate contact 272 and the substrate 254 may not require backside thinning to isolate the substrate 254 in the periphery portion 210 from other portions of the substrate 254 in the image sensor 14. Therefore, in some embodiments, the various trenches may remain partial-depth trenches after all backside thinning (not shown), allowing the substrate 254 to remain electrically intact after backside 258 processing is complete.

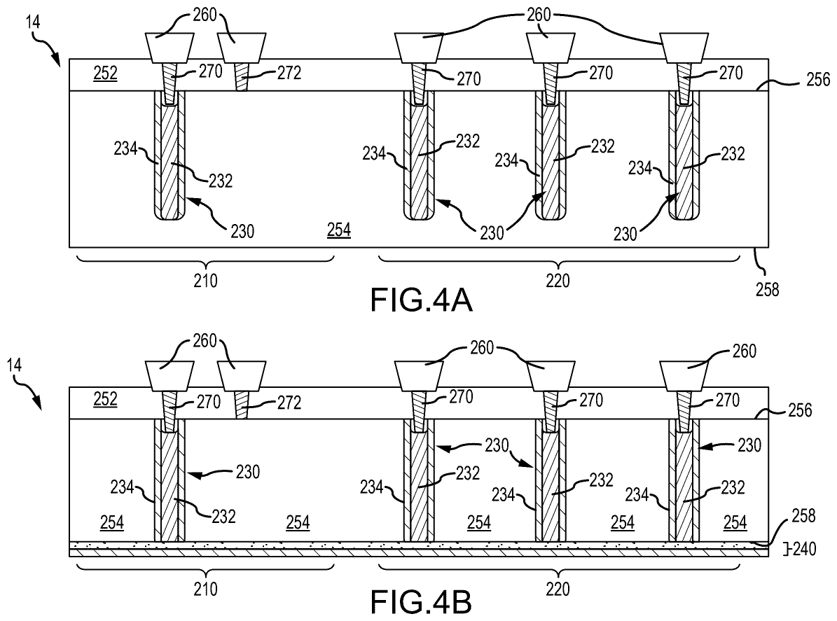

FIG. 4A illustrates an exemplary image sensor 14 after FEOL processing. In some embodiments, a spacer etch may be performed on the insulating material 234 lining the array trenches 230 during FEOL processing, prior to filling with the conductive material 232. The spacer etch may open the insulating material 234 at a bottom surface of the array trenches 230. The opening exposes the bottom of the array trenches 230 to the substrate 254, allowing subsequent conductive coupling of the conductive material 232 with the substrate 254 through the opening. During BEOL processing, excess charge may be discharged through the conductive material 232 and into the substrate 254 at the bottom of the array trench 230.

The substrate 254 and the array trenches 230 may remain at substantially the same electrical potential through the conductive coupling at the bottom of the array trenches 230. In some embodiments, one or more substrate contacts 272 may be provided in the periphery portion 210 as desired to further facilitate equalization of electric potential between the substrate 254 and the array trenches 230.

Referring to FIG. 4B, after BEOL processing, the substrate 254 may be flipped and BS 258 thinning performed, as described above. The BS 258 thinning may remove the bottom portion of the array trenches having the opening in the insulating material 234. The BS 258 thinning may therefore electrically isolate each substrate 254 segment from the conductive material 232 of the array trenches 230. Advantageously, forming image sensors 14 according to various such embodiments may protect array trenches 230 from charge damage during BEOL processing using only structures and processing from the FS 256. For example, image sensors 14 according to various such embodiments do not require BS 258 contacts for protecting or biasing array trenches 230.

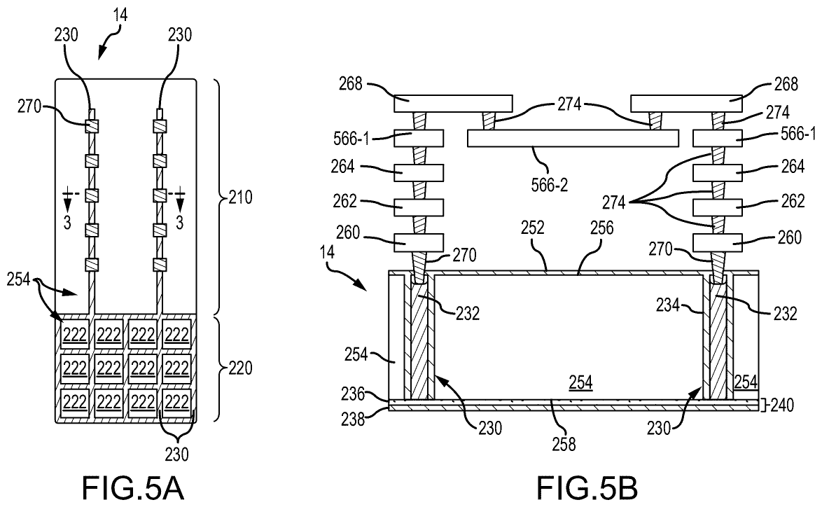

Referring to FIG. 5A, in some embodiments, the substrate 254 in the periphery portion 210 may be electrically isolated from the array trenches 230. For example, the periphery portion 210 may be devoid of any substrate contacts 272. The array trenches 230 may be protected from charge damage from BEOL processing by forming a tall stack of vias and metal layers have a small cross-sectional area and that is left unconnected for trench biasing until the end of BEOL processing.

In some embodiments, referring to FIG. 5B, a trench contact 270 may be coupled through multiple vias 274 and regions of two or more metal layers 260, 262, 264, 266, 268 having a small cross-sectional area. For example, the respective vias and metal layers may be the minimum size required to make electrical connections to lower and/or upper layers, for example based on various process design rules. In an exemplary embodiment, the trench contacts 270 are coupled with small regions of the first metal layer 260, second metal layer 262, third metal layer 264, and fourth metal layer 566-1 during BEOL processing. The small cross-sectional area reduces the risk of charge damage, as described above.

A large region of a metal layer other than the upper-most metal layer may also be formed during BEOL processing, which may be configured to couple with to other image sensor 14 circuitry to eventually provide trench biasing during operation of the image sensor 14. For example, a large region 566-2 of the fourth metal layer 566-2 may be formed and configured for biasing the array trenches 230. The large region 566-2 may receive excess charge during BEOL processing but remains unconnected from the array trenches 230 until the end of BEOL processing. The risk of charge damage to the array trenches 230 and surrounding structures during BEOL processing is therefore significantly reduced.

The large region 566-2 and the small regions 566-1 of the non-uppermost metal layer may be coupled through additional vias to an upper-most metal layer, for example the fifth metal layer 268, at the end of BEOL processing. The coupling of these regions 566-1, 566-2 through the upper-most metal layer provides a path for biasing the array trenches 230 during operation of the image sensor 14. The array trenches 230 have reduced risk of receiving charge damage due to the formation of the upper-most metal layer at the end of BEOL processing. It will be recognized that some embodiments may include substrate contacts 272 in the periphery portion 210 as desired. It will further be recognized that other arrangements of vias and conductive signal lines of the various metal layers may be used for coupling the array trenches 230 and/or substrate 254, with large conductive signal lines remaining unconnected until the end of BEOL processing.

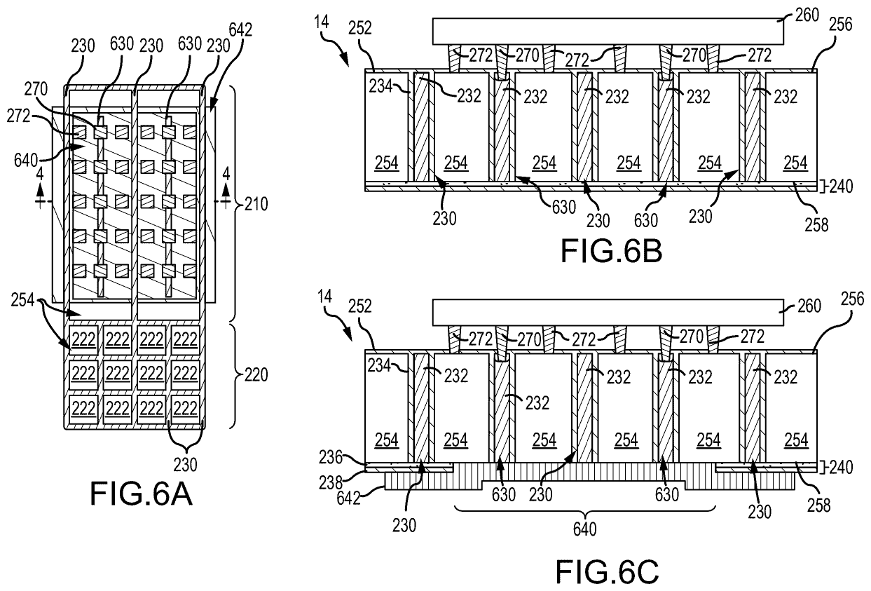

FIG. 6A illustrates a top view of an exemplary image sensor 14 having array isolation structures that are disconnected during BEOL processing and coupled from the BS 258 after BEOL processing to enable biasing of the array isolation structures during operation of the image sensor 14, according to various embodiments. As described with respect to FIG. 2A-C, the image sensor 14 may have an array portion 220 and a periphery portion 210. The periphery portion 210 need not include the entire portion of the substrate 254 external to the array portion 220. The isolation structures for the pixel portion 220 may be biased through a BS 258 connection in the periphery portion 210 after BEOL processing.

For the sake of clarity, a simplified subset of the array portion 220 and periphery portion 210 are shown in FIGS. 6A-C. The actual number of trench structures, pixels, substrate and trench connections, and the like may be much higher in many embodiments. Further, because the various trench structures may be electrically coupled throughout the array portion 220 and/or periphery portion 210, some embodiments may include only a subset of the various trench structures and/or substrate portions having trench and/or substrate connections, respectively.

The image sensor 14 may include arrangements of array trenches 230 and periphery trenches 630. The array trenches 230 may be as described above. The periphery trenches 630 may include trenches that extend, laterally along the substrate 254, through the periphery portion 210 but not the array portion 230. The periphery trenches 630 do not intersect the array trenches 230 and thus are not directly electrically coupled with the array trenches 230 through intersection of the various trenches.

The periphery trenches 630 may include full trench (FT) trenches, deep trench (DT) trenches, and/or any other suitable trench isolation structures. In some embodiments, the periphery trenches 630 may include deep trench isolation (DTI) structures such as frontside deep trench isolation (FDTI) and/or backside deep trench isolation (BDTI). In some embodiments, the periphery trenches 630 are formed at the same time and using the same processes as the array trenches 230.

Referring to FIG. 6B, in some embodiments, the array trenches 230 and the periphery trenches 630 may be formed by etching a trench in the FS 256 of the substrate 254 of the image sensor 14. In some embodiments, the array trenches 230 and periphery trenches 630 may be etched partially through the substrate 254 in both the array portion 220 and periphery portion 210, such that the substrate 254 remains electrically intact throughout the array portion 220 and periphery portion 210, for example as shown in FIG. 2B. In some embodiments, the array trenches 230 and periphery trenches 630 may be etched fully through the substrate 254 in both the array portion 220 and periphery portion 210, such that the substrate 254 in the periphery portion 210 is isolated from the substrate 254 in the array portion 220.

The array trenches 230 and periphery trenches 630 may be lined with an insulating material 234 as described above. The array trenches 230 and the periphery trenches 630 may then be filled with a conductive material filler 232 as described above. The array trenches 230 of the array portion 220 and periphery portion 210 may be electrically coupled, for example through the conductive filler 232, such that they remain at the same electrical potential. The array trenches 230 may be electrically isolated from the periphery trenches 630 during FEOL processing.

Formation of the array trenches 230 and periphery trenches 630 may be performed during FEOL processing of the image sensor 14. In embodiments having array trenches 230 and periphery trenches 630 formed only partially through the substrate 254, the substrate 254 remains electrically intact or otherwise configured to remain at a consistent electrical potential throughout the periphery portion 210 and the array portion 220 at the end of FEOL processing. In embodiments having array trenches 230 and periphery trenches 630 formed fully through the substrate 254, the substrate 254 in the periphery portion 210 is electrically isolated from the substrate 254 in the array portion 220 at the end of FEOL processing.

One or more trench contacts 270 may be formed to one or more periphery trenches 630 in the periphery portion 210. One or more substrate contacts 272 may be formed to one or more segments of the substrate 254 in the periphery portion 210. In some embodiments, FS contacts to the array trenches 230 are not formed during or after FEOL processing, leaving the array trenches 230 electrically isolated from the periphery trenches 630 and substrate 254 segments of the periphery portion 210. The trench contacts 270 and substrate contacts 272 may be formed during or after FEOL processing as desired.

One or more metal routing layers may be formed at the frontside 256 of the substrate 254 during back end of line (BEOL) processing, as described above. A FS passivation layer 252 (for example, an oxide) at the frontside 256 may be part of a first insulating layer (not shown) between the substrate 254 and a first metal layer 260. The trench contacts 270 and substrate contacts 272 may pass through the passivation layer 252 to electrically couple with the periphery trenches 630 and substrate 254 segments, respectively.

The first metal layer 260 may be formed during BEOL processing. In some embodiments, the first metal layer 260 may be electrically coupled with the trench contacts 270 and substrate contacts 272. Through the first metal layer 260, the substrate 254 segments and periphery trenches 630 in the periphery portion 210 will be at substantially the same electrical potential. In other words, the first metal layer 260 may electrically short the substrate 254 segments and periphery trenches 630.

During BEOL processing, the array trenches 230 in the periphery portion 210 and the array portion 220 remain isolated from the periphery trenches 630 and substrate 254 segments. In some embodiments, for example having trench isolation structures that do not extend fully through the substrate 254, the substrate 254 segments in the periphery portion 210 and the array portion 220 will be at substantially the same electrical potential due to the electrically intact portions of the substrate extending along the BS 258 in both the periphery portion 210 and the array portion 220.

Therefore, in some exemplary embodiments, the substrate 254 and periphery trenches 630 in the periphery portion 210 may remain at substantially the same electrical potential during BEOL processing. If various plasma processes performed during BEOL processing create excess charge on one or more metal layers, the periphery trenches 630 and the substrate 254 segments will remain at equivalent electrical potential, minimizing or otherwise reducing the electrical field between the periphery trenches 630 and the surrounding substrate 254. Further, the array trenches 230 remain isolated from the metal routing layers during BEOL processing and will remain isolated from any charge buildup. This significantly reduces the risk of charge damage to the substrate 254 and various trenches 230, 630 of the image sensor 14 during BEOL processing.

After BEOL processing from the FS 256, the substrate may be flipped, for example attached to a carrier wafer, and further processed from the BS 258. If desired, for example in embodiments including trench isolation structures not formed fully through the substrate 254, the substrate 254 may be thinned from the BS 258 to at least the array trenches 230 such that one or more substrate 254 segments are no longer in electrical communication. In some embodiments, the substrate 254 may be thinned from the BS 258 to remove the insulating material 234 from the bottom of the array trenches 230 and periphery trenches 630, to expose the conductive filler 232. In some embodiments, a passivation region 240 may be formed on the BS 258.

Therefore, as represented by FIG. 6B, the substrate 254 segments in the array portion 220 may be electrically isolated from the substrate 254 segments in the periphery portion 210. The substrate 254 segments in the periphery portion 210 may be electrically isolated from the substrate 254 in other portions of the image sensor 14 external to the array portion 220. The substrate 254 segments for each pixel in the array portion 220 may be physically and/or electrically isolated from each other due to the BS 258 thinning and/or full-depth trench formation. The substrate 254 segments in the periphery portion 210 may remain electrically coupled with the periphery trenches 630 through the trench contacts 270 and substrate contacts 272.

Referring to FIG. 6C, the array trenches 230 may be electrically coupled with the periphery trenches 630 after BEOL processing. In some embodiments, a large backside region 640, for example spanning at least one array trench 230 and one periphery trench 630, may be opened in the passivation region 240 in the periphery portion 210. The open large backside region 640 may expose the conductive filler 232 of the array trenches 230 and periphery trenches 630.

A backside conductive layer 642 may be formed, for example via deposition, within the large backside region 640 opening. In some embodiments, the backside conductive layer 642 may also extend over the passivation region 240 surrounding the large backside region 640 opening. In some embodiments, the backside conductive layer 642 may be formed at the same time as and/or from the same material as, but electrically isolated from, a metal layer in array portion 220. For example, the backside conductive layer 642 may be formed from tungsten during the same processing steps as the formation of a tungsten light shield in the pixel array. In some embodiments, the light shield in the pixel array may be grounded, and the backside conductive layer 642 may receive a negative voltage, through the periphery trenches 630, to bias the array trenches 230.

The backside conductive layer 642 may electrically couple the array trenches 230 with the periphery trenches 630 in the periphery portion 210. In some embodiments, the substrate 254 segments in the periphery portion 210 are also electrically coupled, through the backside conductive layer 642, to the array trenches 230 and the periphery trenches 630. In some embodiments, the backside conductive layer 642 may include a metal, for example tungsten. The array trenches 230 may be biased during operation of the image sensor 14 though the electrical coupling of the backside conductive layer 642, periphery trenches 630, trench contacts 270, the first metal layer 260, and other suitable circuitry of the image sensor 14.

Advantageously, according to various embodiments, the array trenches 230 may be isolated from charge damage during BEOL processing and may be electrically coupled to periphery trenches 630 through a conductive layer 642 on the BS 258 to provide bias to the array trenches 230 during operation of the image sensor 14. The conductive layer 642 coupling the periphery trenches 630 to the array trenches 230 may be a relatively low-cost contact due to its relatively large size.

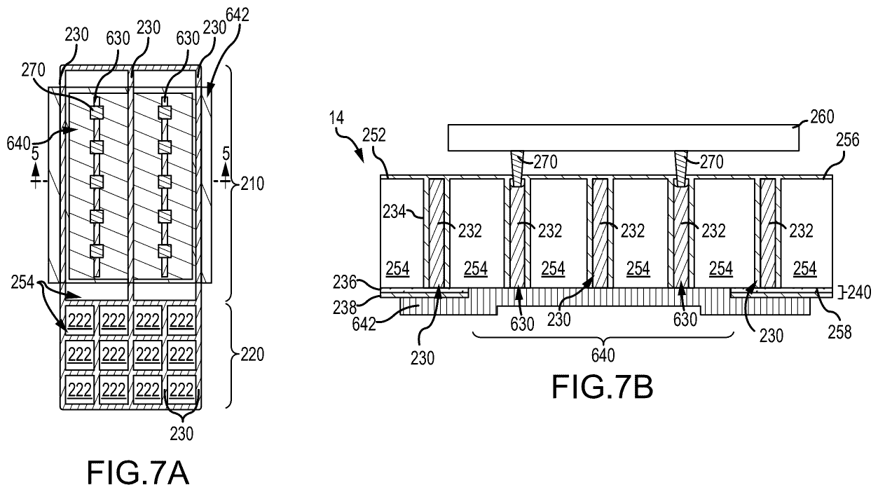

In some embodiments, referring to FIGS. 7A and 7B, the FS 256 substrate contacts 272 from the first metal layer 260 to the substrate 254 segments in the periphery portion 210 may be omitted. Except for the omission of the substrate contacts 272, the formation of the structures of the periphery portion 210 and array portion 220 may remain the same as described with respect to FIGS. 6B and 6C.

During BEOL processing, the periphery trenches 630 may accumulate charge and may not remain at the same electrical potential as the surrounding substrate 254 segments due to the presence of the trench contacts 270 and omission of the substrate contacts 272. Charge damage may occur in or around the periphery trenches 630, and damage may be limited to the periphery portion 220, which may be acceptable. Additionally, the backside conductive layer 642 may electrically couple the periphery trenches 630 and the substrate 254 segments in the periphery portion 210 after BEOL processing, reducing the effect of any charge damage that might have occurred to the periphery trenches 630.

As described above, the array trenches 230 are electrically coupled with the periphery trenches 630 through the backside conductive layer 642 after BEOL processing and are not subjected to charge damage from BEOL processing. Various embodiments omitting the substrate contacts 272 may otherwise provide the same advantages and functionality as described with respect to FIGS. 6A-6C above.

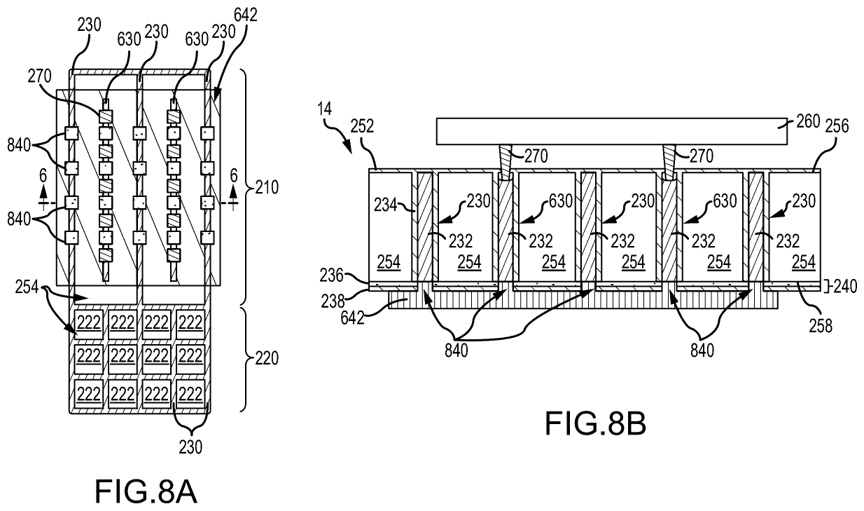

In some embodiments, referring to FIGS. 8A and 8B, one or more small backside regions 840 may be opened in the passivation region 240 instead of or in addition to opening the large backside region 640. The small backside region 840 openings may be aligned with the conductive material filler 232 of the array trenches 230 and periphery trenches 630 in the periphery portion 210, and may avoid opening the passivation region 240 at the substrate 254 segments. The open small backside regions 840 may expose the conductive filler 232 of the array trenches 230 and periphery trenches 630. The small backside region 840 openings allow electrical coupling of the array trenches 230 and periphery trenches 630 through the backside conductive layer 642, while avoiding electrical coupling with the substrate 254.

In some embodiments, the substrate contacts 272 may be omitted as described above. Thus, if desired, the substrate 254 may remain isolated from the periphery trenches 630 and array trenches 230 and their respective biasing during operation of the image sensor 14. In some alternative embodiments, the FS 256 substrate contacts 272 may be included to electrically couple the array trenches 230, periphery trenches 630, and substrate 254 segments in the periphery portion 210.

As described above, the array trenches 230 are electrically coupled with the periphery trenches 630 through the backside conductive layer 642 after BEOL processing and are not subjected to charge damage from BEOL processing. Various embodiments having small backside regions 840 opened in the passivation region 240 and omitting the large backside region 640 opening(s) may otherwise provide the same advantages and functionality as described with respect to FIGS. 6A-6C above.

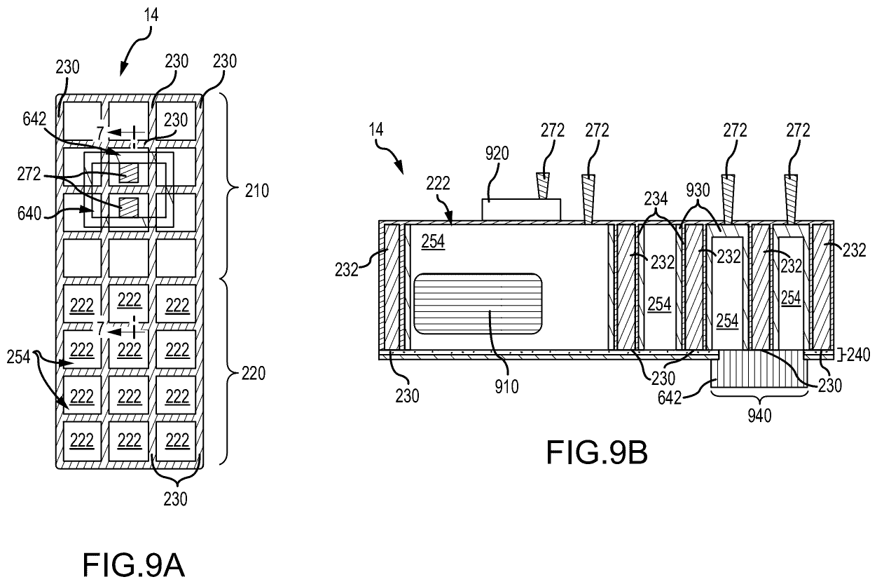

In some embodiments, referring to FIGS. 9A and 9B, the array trenches 230 may be conductively coupled, after BEOL processing, for biasing through a backside conductive layer 642. The backside conductive layer 642 may be formed in a large backside region 940 opened in the passivation region 240 in the periphery portion 210. The large backside region 940 may span at least one array trench 230 and at least one adjacent substrate 254 segment in the periphery portion 210. In some embodiments, the large backside region 940 spans multiple array trenches 230 and multiple substrate 254 segments. One or more of the substrate 254 segments spanned by the large backside region 940 may be coupled with a substrate contact 272 from the FS 256.

FIG. 9B illustrates a simplified cross section of a pixel 222 and the periphery portion 210. The pixel 222 may include a photodiode 910 formed in the substrate 254. The pixel 222 may also include one or more substrate contacts 272 and other structures to perform reset, readout, and other pixel functions. For example, a transistor gate 920 may form part of a transfer transistor (not shown) to transfer charge generated by incident photons, and may be controlled through a substrate contact 272.

In the periphery portion, the substrate 254 adjacent to the array trenches 230 may be highly doped 930 to increase conductivity of the substrate 254 from the FS 256 to the BS 258. The substrate 254 may be doped during formation of the array trenches 230, for example prior to filling with conductive material 232 and/or lining with insulating material 234. The substrate 254 adjacent to the array trenches 230 in the array portion 220 may also become doped during the same process steps.

The doped portions of the substrate 254 in the periphery portion may be coupled with substrate contacts 272. Trench contacts 270 may be omitted. During BEOL processing, the array trenches 230 may therefore remain isolated from any metal routing layers are not exposed to charge damage. After BEOL processing and any BS 258 thinning (as described above), the large backside region 940 may be opened in the passivation region 240. The backside conductive layer 642 may then be formed and may electrically coupled one or more substrate 254 segments to one or more array trenches 230 in the periphery portion 210.

The array trenches are electrically coupled for biasing though the backside conductive layer 642, the highly-doped substrate 930 adjacent to the array trenches 230, and the substrate contacts 272 in the periphery portion 210. The same type of contacts, for example the substrate contacts 272, used in the pixels 222 may be used for biasing the substrate 254 segments in the periphery portion. Advantageously, therefore, only one type of FS 256 contact is required for both the periphery portion 210 and array portion 220 to both protect the array trenches 230 from charge damage as well as provide biasing to the array trenches 230 during operation of the image sensor 14.

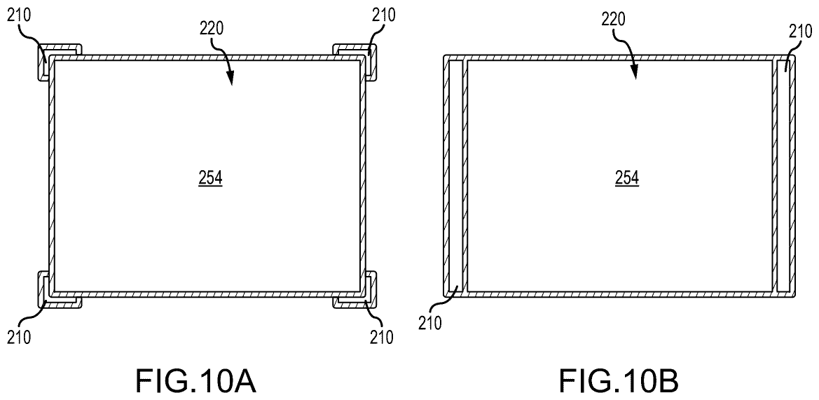

FIGS. 10A and 10B are simplified block diagrams illustrating exemplary arrangements of the array portion 220 and the periphery portion 210. As described above, the image sensor 14 may include other regions on the substrate 254 other than the periphery portion 210 and the array portion 220, and such other regions are not shown for clarity. The periphery portion 210 may be arranged in any suitable manner proximate to the array portion 220. Therefore, it will be recognized that embodiments according to the present disclosure are not limited to those illustrated in the several figures contained herein.

Referring to FIG. 10A, the periphery portion 210 may include one or more substrate regions arranged substantially at one or more corners of the array portion 220, for example at the four corners of the pixel array. The periphery portions 210 may be substantially centered at the corners of the array portion 220, for example forming an “L” shape having equal length sides. The length of the periphery portions 210 along the sides of the array portion 220 may be minimized to minimize the metal area connected to the array trenches 230, periphery trenches 630, and/or other structures during BEOL processing. Minimizing the connected metal area will reduce the risk of charge damage.

Referring to FIG. 10B, the periphery portion 220 may include one or more substrate regions arranged along one or more sides of the array portion 220. For example, the image sensor 14 may include two periphery portions 210 with each arranged on an opposite side of the array portion 220. For further example, the image sensor 14 may include four periphery portions 210 with arranged on one side of the array portion 220 (and, for example, not wrapping around the corners of the array portion 220). Periphery portions 210 extending along one or more sides of the array portion 220 may provide more connections to the array trenches 230, periphery trenches 630, and/or other structures and may therefore lower resistance to the array trenches 230 in the array portion 230.

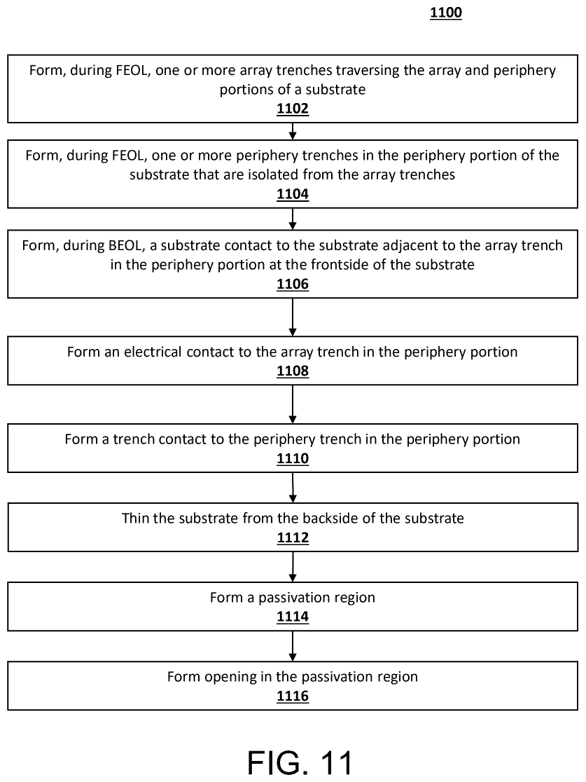

FIG. 11 illustrates a simplified process flow for a method 1100 of protecting array trench structures during formation of an image sensor, for example according to various embodiments described herein. The method may include a step 1102 of forming one or more array trenches in a substrate during FEOL processing, where the array trenches traverse array and periphery portions of the substrate. The trenches may include deep trenches, for example frontside deep trenches. At step 1106, a substrate contact may be formed at the frontside of the substrate during BEOL processing in the periphery portion. The substrate contact may be formed to the substrate adjacent to the array trench. In some embodiments, the formation of the substrate contact may be omitted from the method 1100.

At step 1108, an electrical contact to the array trench may be formed in the periphery portion. In some embodiments, the electrical contact may include a trench contact formed at the frontside of the substrate during BEOL processing. At step 1112, for example after BEOL processing, the substrate may be thinned from the backside of the substrate. In some embodiments, at step 1112, the substrate may be thinned to at least a bottom surface of the array trenches. At step 1114, a passivation region may be formed on the backside of the substrate, for example after the thinning of step 1112.

Some embodiments include separate periphery trenches coupled with array trenches after BEOL processing. In some such embodiments, one or more periphery trenches may be formed during FEOL processing at step 1104. The periphery trenches may remain isolated from the array trenches during FEOL processing. In some such embodiments, at step 1110, a frontside trench contact may be formed to one or more periphery trenches during BEOL processing. Further, at step 1108, the electrical contact to the array trenches may include forming a conductive layer on the backside of the substrate.

The backside electrical contact may be formed during step 1108 after the thinning of step 1112. For example, the electrical contact may be formed after a step 1116 of forming one or more openings in the passivation region at the array trench and periphery trench. The opening(s) may include a large opening spanning the array trench and periphery trench, separated openings at each of the array trench and periphery trench, and/or the like. The array trench may be coupled with the periphery trench via the conductive layer at the opening(s) in the passivation region.

Accordingly, the steps of the exemplary methods described herein can be performed in any suitable order, and the sequences of steps for forming the various structures described herein may be rearranged without departing from the scope of the invention.

Various embodiments therefore provide array trench isolation in a pixel array, biased at a periphery portion of the image sensor. Various embodiments provide several arrangements for biasing array trenches from the periphery while protecting the array trenches from damage during BEOL processing. Systems, devices, and methods as described herein provide for improved charge handling during BEOL processing.

Advantageously, systems, devices, and methods as described herein may provide reduced dark current using biased array trenches, increased yield due to minimizing charge damage, and lower cost through the use of large backside structures and/or standard frontside contacts. While the various trenches and other structures described herein may be referred to as associated with the FS 256 or BS 258, it will be recognized that the structures and processes described herein may be suitably adapted for use on the alternative BS 258 or FS 256. The various trenches, contacts, and other structures may be distributed in the substrate 254 in any suitable manner, and different embodiments may organize the processing of various features in any number of different ways.

The general concepts set forth herein may be adapted to any number of alternate but equivalent embodiments. The term “exemplary” is used herein to represent one example, instance or illustration that may have any number of alternates. Any implementation described herein as “exemplary” is not necessarily to be construed as preferred or advantageous over other implementations, nor is it necessarily intended as a model that must be duplicated in other implementations. While several exemplary embodiments have been presented in the foregoing detailed description, it should be appreciated that a vast number of alternate but equivalent variations exist, and the examples presented herein are not intended to limit the scope, applicability, or configuration of the invention in any way. To the contrary, various changes may be made in the function and arrangement of elements and the ordering of steps described without departing from the scope of the claims and their legal equivalents.

What is claimed is:

1. A semiconductor device, comprising:
a substrate comprising an array portion and a periphery portion;
a plurality of substrate segments defined by a plurality of array trenches in the substrate, the plurality of substrate segments including a first substrate segment in the periphery portion;
a first array trench of the plurality of array trenches, wherein the first array trench traverses the array portion and the periphery portion;
a second array trench of the plurality of array trenches in the array portion, wherein the first array trench intersects with the second array trench in the array portion;
a first trench contact coupled with the first array trench in the periphery portion;
a first substrate contact coupled with the first substrate segment; and
a conductive signal line electrically coupling the first trench contact and the first substrate contact.

2. The semiconductor device of claim 1, wherein the periphery portion is adjacent to the array portion.

3. The semiconductor device of claim 2, wherein:
the periphery portion comprises a plurality of substrate regions; and
each substrate region is located at a corner of the periphery portion.

4. The semiconductor device of claim 1, wherein the first substrate segment is adjacent to the first array trench.

5. The semiconductor device of claim 1, wherein the first trench contact and the first substrate contact are located at a frontside of the substrate.

6. The semiconductor device of claim 1, wherein the plurality of array trenches extend from a frontside of the substrate to a backside of the substrate.

7. The semiconductor device of claim 1, wherein the plurality of array trenches extend from a frontside of the substrate and do not intersect a backside of the substrate.

8. The semiconductor device of claim 1, wherein the first substrate contact is coupled with a protection diode in the first substrate segment.

9. The semiconductor device of claim 1, wherein first array trench comprises:
an insulating material lining; and
a conductive material filler, wherein:
the insulating material lining is open at a bottom surface of the first array trench; and
the conductive material filler is coupled with the substrate through the opening of the insulating material lining.

10. A semiconductor device, comprising:
a substrate comprising an array portion and a periphery portion;
a plurality of array trenches, comprising:
a first array trench traversing both the array portion and the periphery portion; and
a second array trench in the array portion, wherein the first array trench intersects and electrically couples with the second array trench;
a periphery trench in the periphery portion, wherein the periphery trench does not intersect any of the plurality of array trenches;
a trench contact coupled with the periphery trench in the periphery portion, wherein the trench contact is at a frontside of the substrate; and
a conductive layer on a backside of the substrate, wherein the conductive layer couples the periphery trench with the first array trench at the periphery portion.

11. The semiconductor device of claim 10, wherein the substrate comprises a plurality of substrate segments defined by the periphery trench and the first array trench, wherein the semiconductor device further comprises:
a substrate contact coupled with at least one of the plurality of substrate segments at the frontside in the periphery portion, wherein the trench contact and the substrate contact are electrically coupled through a conductive signal line.

12. The semiconductor device of claim 10, further comprising:
a passivation region on the backside of the substrate, wherein the conductive layer couples with the periphery trench and the first array trench through a large opening in the passivation region.

13. The semiconductor device of claim 10, further comprising:
a passivation region on the backside of the substrate, wherein:
the conductive layer couples with the periphery trench and the first array trench through a first small opening in the passivation region at the periphery trench and a second small opening in the passivation region at the first array trench; and
the conductive layer does not couple with the substrate between the periphery trench and the first array trench.

14. The semiconductor device of claim 10, wherein the plurality of array trenches and the periphery trench extend from the frontside of the substrate to the backside of the substrate.

15. The semiconductor device of claim 10, wherein:
the array portion comprises a plurality of pixels; and
the plurality of array trenches define the plurality of pixels.

16. A method of forming an image sensor on a substrate, comprising:
forming, during front end of line (FEOL) processing, a plurality of deep trenches from a frontside of the substrate, wherein:
the plurality of deep trenches are formed in an array portion of the substrate and in a periphery portion of the substrate; and
a first trench of the plurality of deep trenches comprises an array trench traversing the array portion and the periphery portion;
forming in the periphery portion, during back end of line (BEOL) processing, a substrate contact to the substrate adjacent to the first trench at the frontside of the substrate;
forming an electrical contact to the first trench in the periphery portion; and
thinning, after BEOL processing, the substrate from a backside of the substrate.

17. The method of claim 16, wherein the electrical contact comprises a trench contact formed at the frontside of the substrate during BEOL processing.

18. The method of claim 16, wherein the step of thinning comprises thinning the substrate to at least a bottom surface of the plurality of deep trenches.

19. The method of claim 16, wherein a second trench of the plurality of deep trenches comprises a periphery trench isolated, during FEOL processing, from the first trench, the method further comprising:
forming a trench contact, at the frontside of the substrate, to the second trench in the periphery portion, wherein:
the electrical contact comprises a conductive layer on a backside of the substrate; and
the conductive layer couples the first trench with the second trench at the periphery portion.

20. The method of claim 19, further comprising:
forming a passivation region on the backside of the substrate after the step of thinning; and
forming one or more openings in the passivation region at the first trench and the second trench, wherein the conductive layer couples the first trench with the second trench through the one or more openings.
